(19) United States
(12) Patent Application Publication
(10) Pub. No.: US 2007/0040238 A1
(43) Pub. Date: Feb. 22, 2007

(54) COIL STRUCTURE, METHOD FOR MANUFACTURING THE SAME AND SEMICONDUCTOR PACKAGE

(75) Inventors: Tomoo Yamasaki, Nagano-shi, Nagano (JP); Yasuyoshi Horikawa, Nagano-shi, Nagano (JP)

Correspondence Address: RANKIN, HILL, PORTER & CLARK LLP, 4080 ERIE STREET, WILLOUGHBY, OH, 44094-7836, US

(73) Assignee: SHINKO ELECTRIC INDUSTRIES CO., LTD., Nagano-shi (JP)

(21) Appl. No.: 11/463,172

(22) Filed: Aug. 8, 2006

(30) Foreign Application Priority Data
Aug. 19, 2005 (JP) 2005-238936

(51) Int. Cl. H01L 29/00

(52) U.S. Cl. 257/531

(57) ABSTRACT

A chip coil has a chip format including a rectangle substrate of an insulating resin material and a coil portion having a solenoid structure a part of which is embedded within the substrate and in which adjacent coils are insulated from each other by the substrate. The resin material contains a magnetic filler. The chip coil has a thickness of 50 μm or less.

### BACKGROUND OF THE INVENTION

This invention relates to a passive component, and more specifically to a chip-format coil structure and its manufacturing method. This invention also relates to a semiconductor package incorporating the chip-format coil structure.

As well known, a semiconductor system operates in such a manner that a chip-type capacitor, coil and resistor which are passive components are surface-mounted in a semiconductor package. Although the semiconductor package is widely used in various electronic devices such as a cellular phone and a note-book PC, its down-sizing is proceeding according to the degree of sophistication and miniaturization of the electronic devices.

Meanwhile, where the chip-format coil is surface-mounted in the semiconductor package, for example, the method as shown in FIG. 1 is generally adopted. In the example shown in FIG. 1, an LSI chip 120 and a chip coil 130 having a solenoid structure are loaded on the surface of a semiconductor chip 110. The chip coil 130 has a structure in which a conductor coil 132 is wound around the body of an insulating core 131. The distal ends of the conductor coil 132 cylindrically wound are connected to electrodes 133 and 134. The electrodes 133 and 134 of the chip coil 130 are fixed to the semiconductor package 110 through solder bumps 135 and 136, respectively. However, the technique of surface mounting has a limitation in downsizing the chip coil so that it is difficult to greatly downsize the semiconductor package. This is because the size of the semiconductor package depend on the areas of an LSI chip and the chip coil. In addition, since the technique of surface mounting adopts the solder connection for the surface mounting of the chip coil and so deterioration in reliability due to poor connection is problematic.

In order to solve the problem of the chip coil as described above, the method for incorporating a coil in the semiconductor package has been also proposed. For example, Patent Reference 1 discloses the semiconductor device incorporating the coil as shown in FIG. 2. In this semiconductor device, a semiconductor substrate 201 having an underlying insulating film 203 is employed. On a lower insulating layer 205 on the underlying insulating film 203, a plurality of conductive films 207 are formed. Above the lower insulating layer 205, a plate-like magnetic body 213 is formed through a PSG film 209 and an SiN film 211. In the PSG film 209, the SiN film 211 and a photosensitive polyimide layer 215 on the lower conductive films 207, through-holes 217 are formed. On the bottom of the through-holes 217, barrier metals 218 are formed, respectively. On the photosensitive polyimide layer 215 and within the through-holes 217, a plurality of upper conductive film 219 are formed so that all the lower conductive films 207 are connected in series, and sealed with an insulating resin 221. Thus, in the case of this semiconductor device, the lower conductive films 207 and upper conductive films 219 constitute the coil.

However, such a semiconductor device incorporating the coil still presents a problem. For example, since the semiconductor substrate is indispensable, the structure of the semiconductor device is restricted. So, any semiconductor device cannot incorporate the coil. If possible, it is desirable that the coil can be employed as a single component. Further, since the structure of the above semiconductor device is complicate, its manufacturing process is complicate and its manufacturing cost also increases. Further, since the plate-like magnetic body must be used, when it is desired to control or increase the inductance value of the coil, it is difficult to simply satisfy such a requirement.

Patent Reference 1: JP-A-2003-203982 (Claims, FIG. 1)

### SUMMARY OF THE INVENTION

An object of this invention is to solve the problems of a conventional chip coil and a semiconductor device incorporating the chip coil thereby to provide a chip coil (chip-format coil) capable of contributing to downsizing and sophistication of the semiconductor device and not deteriorating the reliability of the device owing to poor connection.

Another object of this invention is to provide a chip coil which can be used as a single coil component so as to not restrict the device structure when it is incorporated within the semiconductor device and also can easily control or increase the inductance value.

Still another object of this invention is to provide a method for manufacturing such a chip coil accurately and with high yield by means of a simple technique.

A further object of this invention is to provide a downsized and sophisticated semiconductor package equipped with the chip coil described above.

The above and other objects of this invention will be easily understood from the following detailed explanation.

In accordance with the one aspect of this invention, this invention provides a chip-format coil structure including:

a rectangle substrate of an insulating resin material; and

a coil portion having a solenoid structure a part of which is embedded within the substrate and in which adjacent coils are insulated from each other by the substrate.

In accordance with another aspect of this invention, this invention provides a method for manufacturing a chip-format coil structure including a rectangle substrate of an insulating resin material and a coil portion having a solenoid structure a part of which is embedded within the substrate and in which adjacent coils are insulated from each other by the substrate, the method including the steps of:

forming successively the substrate and the coil portion on a provisional support; and

taking out the coil structure by removing the support and forming the coil portion as a coupling body including a plurality of rectangle coils, wherein

each of the rectangle coils is made by a method including the step of:

forming a lower wiring on the provisional support;

stacking an insulating resin material with a thickness necessary to obtain a thickness of the substrate on the provisional support;

making via holes vertically passing through a layer of the resin material;

filling the via holes with a conductive metal;

covering the surface of the layer of the resin material with a predetermined pattern; and

forming a first passing-through wiring which vertically passes through the substrate and whose lower end is connected to one end of the lower wiring, an upper wiring which is formed on the upper surface of the substrate and whose one end is connected to one upper end of the first passing-through wiring, and a second passing-through wiring which vertically passes through the substrate, whose upper end is connected to the other end of the upper wiring and whose lower end is connected to the one end of the lower wiring of an adjacent coil.

In accordance with still another aspect of this invention, this invention provides a semiconductor package incorporating the coil structure according to this invention.

In accordance with this invention, as understood from the following detailed description, since a chip-format coil with high performance which can be employed as a single component could be realized, it can be built in various electric devices, e.g. semiconductor device or semiconductor package, thus contributing to its downsizing and sophistication. Further, since the coil could be built in the device, connection of the chip coil using soldering is not required, thereby enhancing reliability of the device.

Further, since the chip coil according to this invention can be employed as a single coil component, unlike a conventional technique, it is not necessary to prepare a substrate and make the chip coil on the substrate through sequential processing steps. Thus, the chip coil can be easily built in so that any trouble can be avoided while the chip coil is being manufactured. In addition, in incorporating the chip coil in the semiconductor device, its use is not limited by the structure of the device and so the degree of freedom of manufacture can be increased. Where a magnetic filler is dispersed in the insulating resin material, unlike before, it is not necessary to arrange a plate-like magnetic body so that in this aspect also, the degree of freedom of manufacture and further the inductance value can be easily controlled or increased.

Further, in accordance with this invention, the coil structure according to this invention can be manufactured exactly and with high yield by a simple technique.

Further, in accordance with this invention, a down-sized and sophisticated semiconductor package incorporating the coil structure according to this invention can be provided.

### BRIEF DESCRIPTION OF THE DRAWINGS

FIG. 1 is a sectional view of a conventional semiconductor chip with a chip coil being surface-mounted.

FIG. 2 is a sectional view of a conventional coil built-in semiconductor device in which a coil is made on a substrate.

FIGS. 3A and 3B are a sectional view and a plan view showing an embodiment of the chip-format coil structure according to this invention.

FIG. 4 is a sectional view showing an example of the chip-format coil built-in semiconductor package according to this invention.

FIGS. 5A to 5H are sectional views showing the method for manufacturing a chip-format coil structure according to this invention.

FIGS. 6A to 6C are plan views showing the state of a workpiece according to the manufacturing method shown in FIG. 5.

FIGS. 7A to 7C are sectional views showing a modification of the manufacturing method shown in FIG. 5.

FIG. 8 is a sectional view and a plan view showing another embodiment of the chip-format coil structure according to this invention.

FIGS. 9A to 9F are sectional views showing an embodiment of the semiconductor package according to this invention.

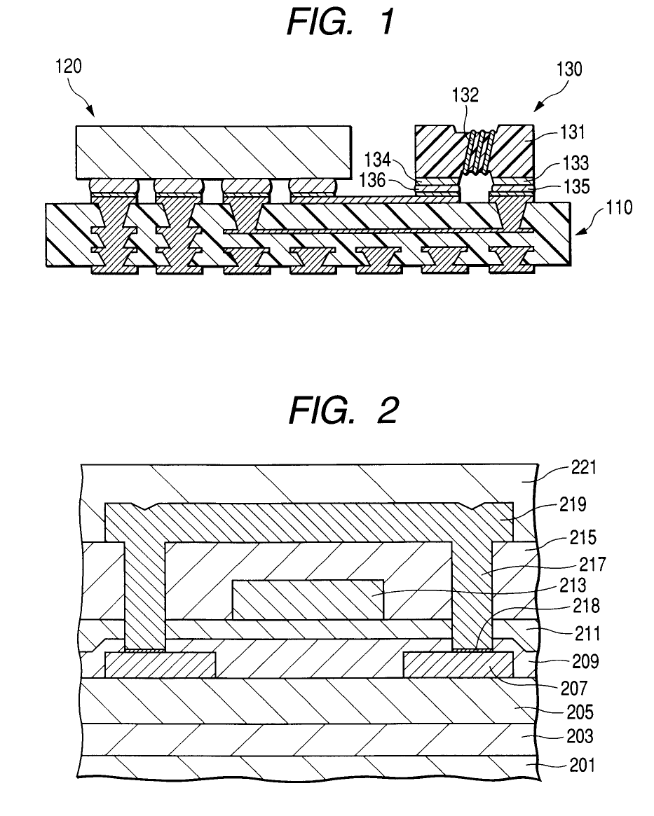

### DETAILED DESCRIPTION OF THE PREFERRED EMBODIMENTS

According to this invention, a coil structure, a method for manufacturing the coil structure and a semiconductor package can be appropriately carried out in various manners. Now referring to the attached drawings, an explanation will be given of preferred embodiments of this invention. However, it should be noted that this invention should not be limited by these embodiments.

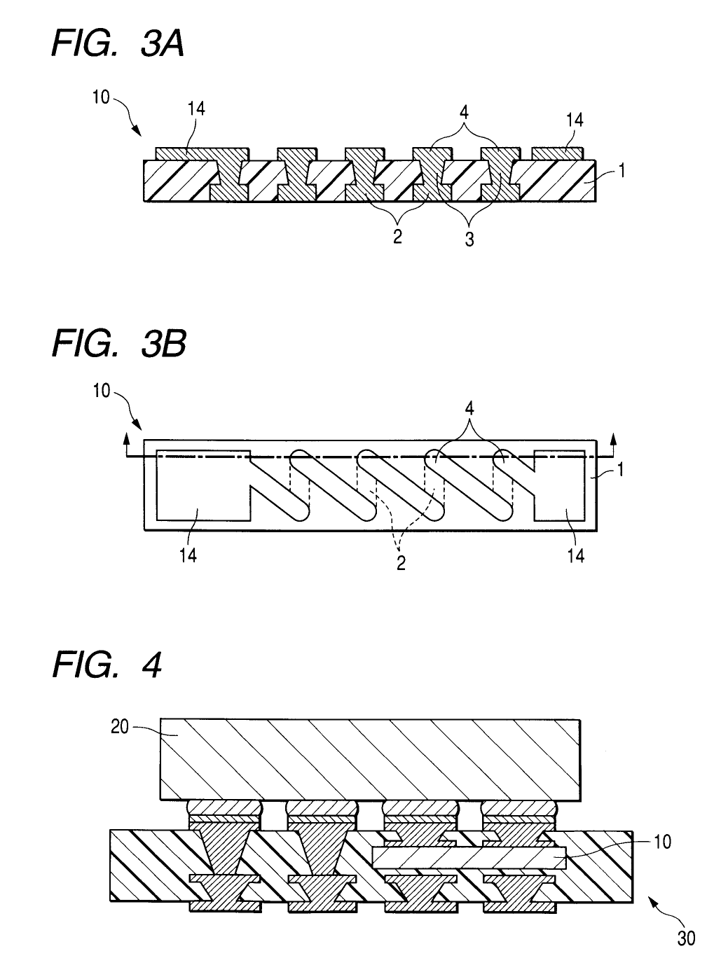

FIGS. 3A and 3B show a preferred embodiment of a chip-format coil structure 10 according to this invention. As seen from FIG. 3A, the chip-format coil structure 10 includes a rectangle substrate 1 and a coil portion 2, 3 and 4 having a solenoid structure at least a part of which is embedded within the substrate 1 and in which adjacent coils are insulated from each other by the substrate 1. The coil portion is rectangle whereas an ordinary coil is cylindrical. When the coil structure 10 is seen from above, only the upper wiring 4 formed in a pattern shape is exposed and its both ends are connected to electrodes 14.

Although the substrate can be formed of various insulating materials, it may preferably be formed of an insulating resin material. The resin material useful to form the substrate is a resin which is generally used to manufacture the chip coil and semiconductor package. Particularly, where the coil structure is incorporated in the semiconductor package, it is desirable that the coil structure is made of the same material as the semiconductor package. The preferable resin material, although not limited to the materials listed in the following, is polyimide.

The substrate can be formed by various techniques using the resin material. Generally, a resin solution maybe applied and hardened by an appropriate coating technique, a resin film maybe affixed, or otherwise a resin coating may be precipitated by electrodeposition. Further, the substrate can be used to have various thicknesses. Particularly, the thickness of the substrate is preferably determined taking the thickness of an objective coil structure in consideration. The thickness of the substrate is commonly in a range of about 20 to 50 μm. The thickness of the substrate may be changed according a desired inductance value of the coil structure.

As understood from FIGS. 3A and 3B, the coil portion is a coupling body including a plurality of rectangle coils. Each rectangle coil includes a lower wiring 2 formed on the lower surface of the substrate 1, a first passing-through wiring 3 which vertically passes through the substrate land whose lower end is connected to the one end of the lower wiring 2, an upper wiring 4 which is formed on the upper surface of the substrate 1 and whose one end is connected to the one upper end of the first passing-through wiring 3 and a second passing-through wiring 3 which vertically passes through the substrate 1, whose upper end is connected to another end of the upper-wiring 4 and whose lower end is connected to the one end of the lower wiring 2 of an adjacent coil. Both ends of the upper wiring 4 are connected to the electrodes 14.

The coil portion inclusive of the electrodes can be formed of various conductive materials. The coil portion can be preferably formed of e.g. a conductive metal such as copper. The coil portion can be formed by various techniques according to the position of the coil. For example, the passing-through wirings can be formed by filling via holes previously formed with the conductive metal by any technique, e.g. plating. Further, the flat pattern portion such as the upper wiring, lower wiring and electrode can be optionally formed for example by plating the conductive metal or affixing a foil of the conductive metal. Particularly, plating of the conductive metal is useful since the passing-through wiring, upper wiring and electrode can be collectively made.

The coil portion can be formed with various sizes according to the structure and impedance value of a desired coil structure. For example, the thickness of the coil portion is generally within a range of about 10 to 15 μm in each of the upper wiring, lower wiring and electrode. The width of the coil portion in each of them is usually within a range of about 15 to 30 μm. Further, the diameter of the passing-through wiring is usually within a range of about 15 to 30 μm.

The coil structure according to this invention is rectangle, and its size can be changed in a wide range according to the structure and use of a desired coil structure. For example, the length of the coil structure is within a range of about 200 μm to 10 mm, and the width of the coil structure is within a range of about 200 μm to 10 mm. In the case of the coil structure according to this invention, particularly, attention should be given to the thickness. This is because it is intended that the coil structure according to this invention is used particularly in the state where it is incorporated in the semiconductor package, and so the coil structure is preferably formed as thin as possible. The thickness of the coil structure is usually about 50 μm or less. Although the lower limit of the thickness of the coil structure is not particularly limited, considering the machining technique generally adopted at present, it is usually about 30 μm and its proximity. Namely, the thickness of the coil structure is preferably within a range of about 30 to 50 μm, more preferably within a range of 35 to 45 μm.

The coil structure according to this invention is characterized by the matters described above, but can be changed in various manners within a scope of this invention. For example, where the substrate 1 is formed as shown in FIG. 8, a magnetic filler 1 is preferably further dispersed in the resin material. This is because by dispersing the magnetic filler 11, the inductance value of the coil structure 10 formed can be increased or optionally controlled. The magnetic filler adopted preferably in carrying out this invention is e.g. a filler of a material having a high magnetic permeability such as iron, nickel, cobalt, manganese, zinc, iron-nickel alloy and permalloy. These fillers can be employed with various grain diameters, but are preferably usually employed with the grain diameter within a range of about 0.1 to 10 μm. Further, the dispersing degree of these fillers can be changed within a wide range, but is preferably usually within a range of 30 to 85% by weight with reference to the total weight of the resin material.

As described above, in the coil structure according to this invention, its inductance value can be optionally changed according to e.g. the adjustment of the size of the coil and dispersing degree of the magnetic filler in the resin material. Their examples are described below.

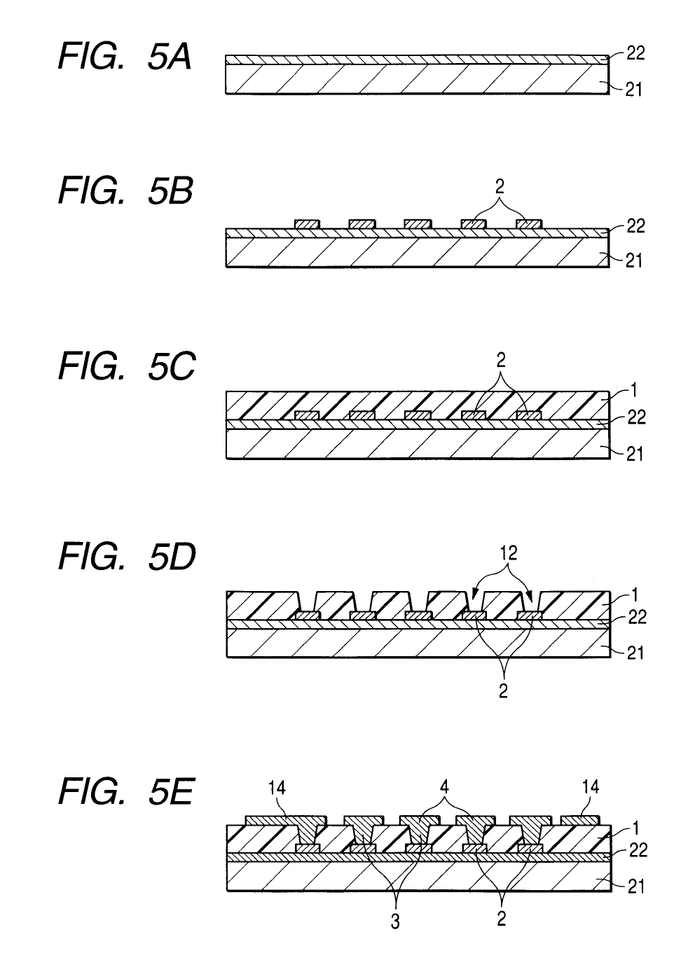

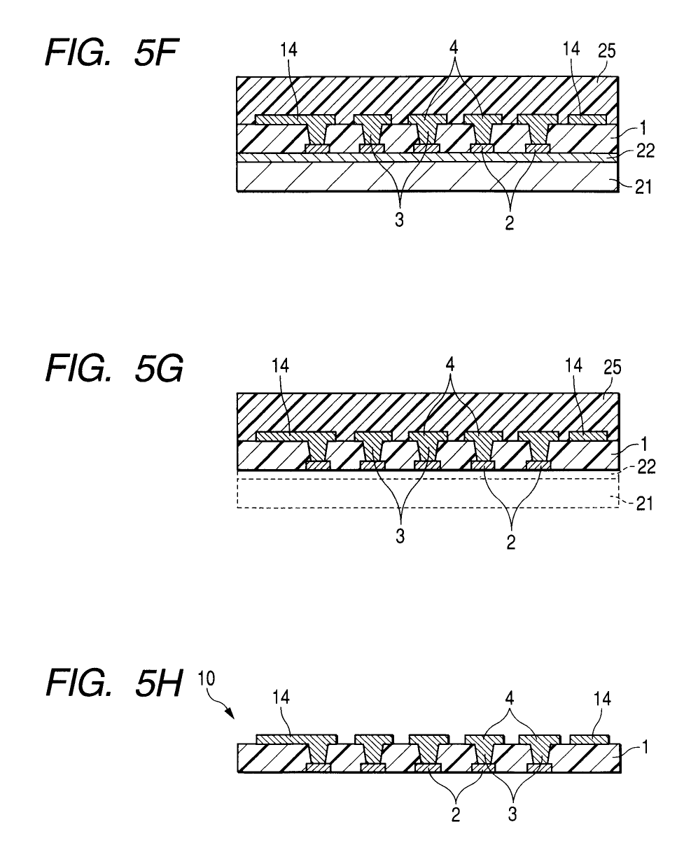

Three kinds of chip coils Nos. 1, 2 and 3 whose size and number of turns indicated in the following Table 1 have been made according to the method which will be explained below referring to FIGS. 5A to 5H. The chip coil No. 2 is a chip coil in which the width D of the chip coil No. 1 is reduced by 5.00 E−04 (m). The chip coil No. 3 is a chip coil in which in the chip coil No. 1, the relative permeability (Z) is increased to 1.00 E+01 by doping the insulating resin material of the substrate with a magnetic filler (Ni powder). The measurement result of the respective measured inductances L (nH) of the chip coils is shown in Table 1.

TABLE 1

| | | |
|---|---|---|
| Chip Coil | Chip Coil | Chip Coil |
| No. 1 | No. 2 | No. 3 |

| | | | |
|---|---|---|---|
| Coil Length 1(m) | 1.00 × 10⁻³ | 1.00 × 10⁻³ | 1.00 × 10⁻³ |
| Coil Width D(m) | 1.00 × 10⁻³ | 5.00 × 10⁻⁴ | 1.00 × 10⁻³ |
| Coil Height H(m) | 5.00 × 10⁻⁵ | 5.00 × 10⁻⁵ | 5.00 × 10⁻⁵ |
| Coil Number of | 5.00 × 10⁰ | 5.00 × 10⁰ | 5.00 × 10⁰ |
| Turns N (number of | | | |
| times) | | | |
| Relative | 1.00 × 10⁰ | 1.00 × 10⁰ | 1.00 × 10⁺¹ |
| Permeability (μ) | | | |
| Vacuum | 1.26 × 10⁻⁶ | 1.26 × 10⁻⁶ | 1.26 × 10⁻⁶ |
| Permeability (μ0) | | | |
| Inductance L (nH) | 1.57 | 0.79 | 15.71 |

As understood from the result indicated in the above Table 1, with the same type of chip coil, the inductance L can be also reduced by reducing the coil width. On the contrary, by increasing the relative permeability, the inductance L can be greatly increased.

The coil structure according to this invention, i.e. a chip-format coil structure including a rectangle substrate of an insulating material and a coil portion having a solenoid structure a part of which is embedded within the substrate and whose adjacent coils are insulated by the substrate, can be manufactured by means of various methods. As a result of investigation to find out the useful method for manufacturing the chip-format coil structure, the inventors of this invention have found that it is effective to make the coil structure on a provisional support and thereafter to take out the coil structure by removing the provisional support which has become unnecessary, thus completing the method according to this invention. According to this method, the coil structure can be taken out as a coil component without adopting the manner in which the coil structure is supported by the substrate.

In the coil structure according to this invention, the coil portion includes a plurality of rectangle coils which are coupled and integrated. Each rectangle coil can be preferably made through the following steps of:

forming a lower wiring on a provisional support;

stacking an insulating resin material with a thickness necessary to obtain a thickness of a substrate on the provisional support;

making via holes vertically passing through a layer of the resin material;

filling the via holes with a conductive metal;

covering the surface of the layer of the resin material with a predetermined pattern; and

form a first passing-through wiring which vertically passes through the substrate and whose lower end is connected to one end of the lower wiring, an upper wiring which is formed on the upper surface of the substrate and whose one end is connected to one upper end of the first passing-through wiring, and a second passing-through wiring which vertically passes through the substrate, whose upper end is connected to the other end of the upper wiring and whose lower end is connected to one end of the lower wiring of an adjacent coil.

The method for manufacturing such a coil structure can be advantageously carried out in the process as shown in e.g. FIGS. 5A to 5H.

First, as shown in FIG. 5A, a provisional support 21 is prepared. In this embodiment, a copper (Cu) plate is prepared as the provisional support 21. However, without being limited to the copper plate, other metallic plates may be adopted. Otherwise, a silicon plate, a glass plate, etc. may be employed. Next, a stopper layer 22 is formed on the support (Cu plate) 21 thus prepared. The stopper layer 22 serves to prevent the underlying Cu plate from being eroded by the subsequent treating steps. The stopper layer 22 can be formed by depositing e.g. nickel (Ni) or chrome (Cr) with a thickness of about 50 to 200 nm. In order to form the stopper layer 22, e.g. a sputtering process can be adopted.

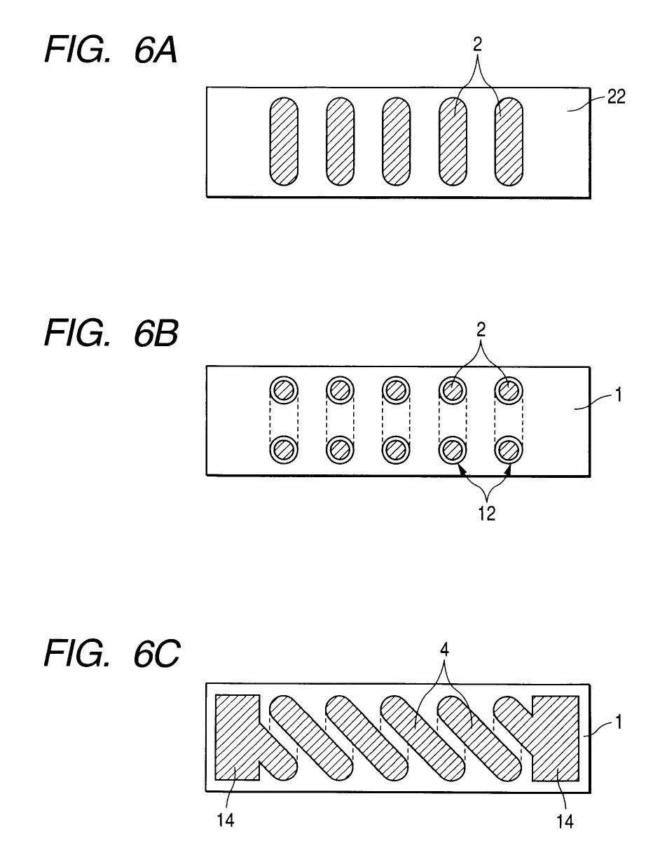

Subsequently, as shown in FIG. 5B, lower wirings 2 with a predetermined pattern are formed. In this embodiment, by a semi-additive technique, the lower wirings 2 are formed by electrolytic Cu plating. Further, before the Cu plating is carried out, although not shown, a Cu layer having a thickness of 500 nm is sputtering-deposited on the stopper layer 22 so that it serves as a seed layer of the Cu plating. The thickness of the lower wirings 2 which constitutes a part of the coil wiring is about 10 to 15 μm. FIG. 6A shows the state when the lower wirings 2 are seen from above the support 21.

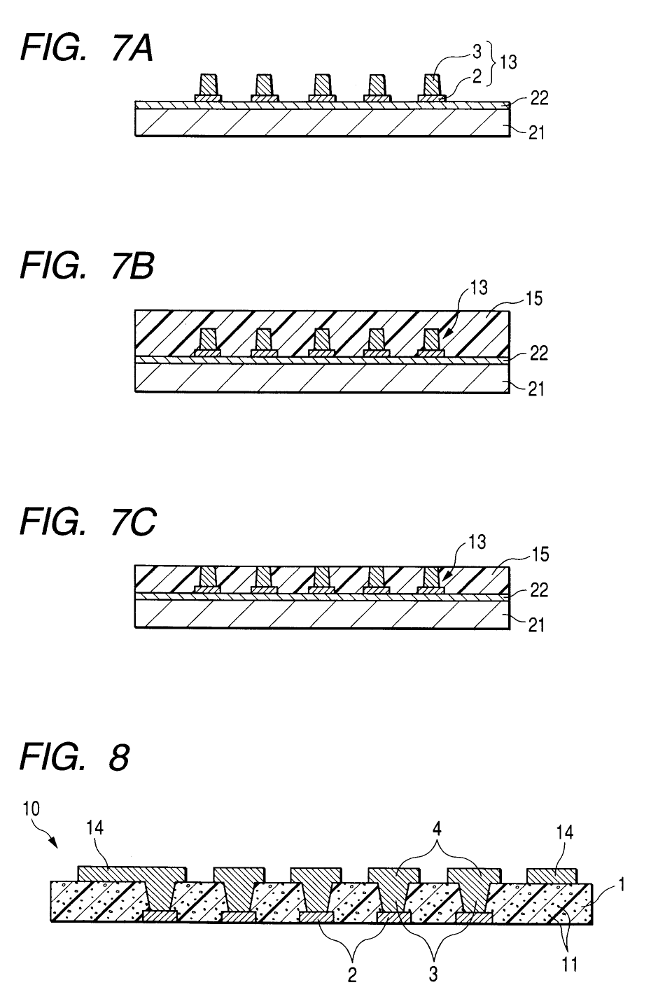

After the lower wirings 2 have been formed, as shown in FIG. 5C, in order to form a substrate of the coil structure, an insulating resin material 1 is stacked with a thickness of about 20 to 50 μm. The resin material employed in this embodiment is polyimide but may be other resin materials. For example, the same resin material as that employed for the semiconductor package is useful. The thickness of the insulating resin layer 1 can be changed according to a desired inductance value. In this embodiment, the insulating resin layer 1 is formed by applying the polyimide resin and hardening it, but it may be formed by affixing a resin film, or otherwise may be precipitated by electrodeposition as explained later with reference to FIGS. 7A to 7C.

After the insulating resin layer 1 has been formed, as shown in FIG. 5D, via holes 12 are made at the positions where the passing through electrodes are formed. The via holes 12 can be opened with a diameter with a diameter of about 50 μm by the laser processing. FIG. 6B shows the state when the insulating resin layer 1 after hole-made is seen from above the support 21. As seen, the lower wirings 2 are exposed at the via holes 12.

Next, as shown in FIG. 5E, passing-through wirings 3 and upper wirings 4 which constitute a part of the coil wiring are formed. In this embodiment, in order to simultaneously form these wirings and also simultaneously form electrodes 14, the electrolytic Cu plating is adopted. The via holes 12 are filled with Cu to form the passing-through wirings 3. On the via holes 12 and insulating resin layer 1, the upper wirings 4 and the electrodes 14 which have a thickness of about 10 to 15 μm are formed. FIG. 6C shows the pattern of the upper wirings 4 and electrodes 14 thus obtained.

After the coil wiring is completed via a series of processing steps, a step of separating the coil structure will proceed. First, as shown in FIG. 5F, in order to protect the coil wiring thus completed from etching, the coil wiring side of the support 21 is covered with an etching protecting film 25 and protected. In this embodiment, although a dry film resist which is commercially available is as the etching protecting film 25, other protecting means may be adopted.

Subsequently, as shown in FIG. 5G, the support 21 and stopper layer 22 are successively removed by etching. In this embodiment, since the Cu plate is used as the support 21, these layers are removed by wet etching usually adopted.

Upon completion of the etching, the etching protecting film 25 which has become unnecessary is flaked off using an alkaline solution (e.g. NaOH). Thus, as shown in FIG. 5H, the objective coil structure 10 can be obtained.

In the manufacturing process described above, the substrate 1 is formed by applying the insulating resin material and hardening it, but as shown in FIGS. 7A to 7C, may be precipitated by electrodeposition. Specifically, in the case of electrodeposition, after the stopper layer 22 has been formed on the support 21 in the procedure of FIG. 5A, via posts 13 are formed as shown in FIG. 7A. Each via post 13 includes the lower wiring 2 and passing-through wiring 3 and is made of Cu. Next, as shown in FIG. 7B, an insulating resin material 15 is stacked with a thickness enough to completely cover the via posts 13 is deposited by electrodeposition. The resin material used in this embodiment is polyimide resin, but may be any other resin material. Next, the as shown in FIG. 7C, the insulating resin layer 15 formed by electrodeposition is subjected to flattening/polishing processing so that the upper end face of each via post 13 (passing-through wiring 3) is exposed. The subsequent steps can be carried out as shown in FIGS. 5E to 5H.

FIG. 4 shows an example of a semiconductor package incorporating the chip coil according to this invention. As seen from FIG. 4, the coil structure 10 according to this invention is built in a semiconductor package 30. In addition, an LSI chip 20 is mounted on the surface of the semiconductor package 30. The semiconductor package 30 can have the same construction as that generally known.

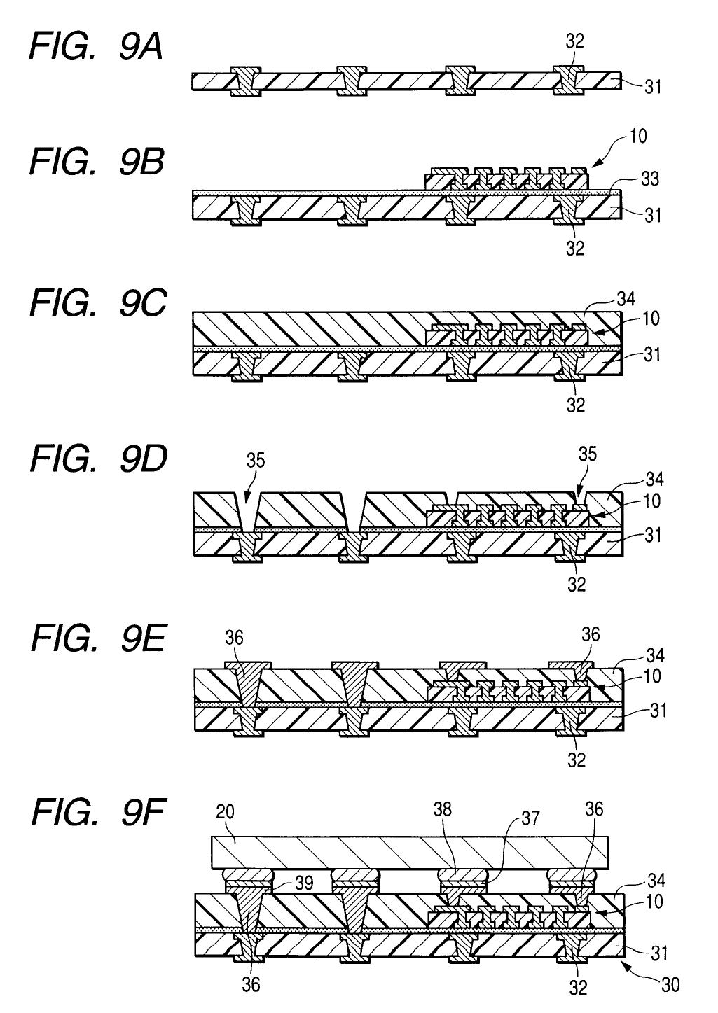

The semiconductor package 30 shown in FIG. 4 incorporating the chip coil can be manufactured by the method as shown in FIGS. 9A to 9F. It should be noted that an illustrated coil semiconductor 10 has been manufactured in another place by the method as shown in FIGS. 5A to 5H.

First, as shown in FIG. 9A, a printed wiring board 31 is prepared and a via wiring 32 is formed therein with Cu plating.

Next, as shown in FIG. 9B, an insulating bonding film (e.g. a “die-attach film”) 33 is affixed on the surface of the printed wiring board 31. Thereafter, a coil structure 10, which has been made and prepared separately, is bonded and loaded thereon. The bonding film 33 is preferably made of the insulating film which is the same as and similar to the semiconductor package.

After the coil structure 10 has been loaded, as shown in FIG. 9C, an insulating resin material 34 is deposited with a thickness enough to completely cover the coil structure 10. The technique of deposition may be application, film affixing, electrodeposition, etc.

After the insulating resin has been deposited, as shown in FIG. 9D, via holes 35 are made at the positions where the via wirings are formed. The via holes 35 can be made by e.g. laser processing.

Next, as shown in FIG. 9E, in order to form the via wirings and electrodes, the electrolytic CU plating is executed. Thus, the via holes 35 are filled with Cu to form the via wirings 36 and an electrode 39 of Cu.

According to the process described above, after the semiconductor package 30 incorporating the coil structure 10 has been completed, as shown in FIG. 9F, an LSI 20 is loaded through the exposed electrode 39. In this embodiment, after nickel plating 37 is made on the electrode 39, the LSI chip 20 has been loaded using solder bumps 38.

What is claimed is:

1. A chip-format coil structure comprising:
a rectangle substrate of an insulating resin material; and
a coil portion having a solenoid structure a part of which is embedded within the substrate and in which adjacent coils are insulated from each other by the substrate.

2. The chip-format structure according to claim 1, wherein
the coil portion is a coupling body including a plurality of rectangle coils, and
each of the rectangle coils includes:
a lower wiring formed on the lower surface of the substrate,
a first passing-through wiring which vertically passes through the substrate and whose lower end is -connected to the one end of the lower wiring,
an upper wiring which is formed on the upper surface of the substrate and whose one end is connected to the one upper end of the first passing-through wiring and a second passing-through wiring which vertically passes through the substrate, whose upper end is connected to another end of the upper wiring and whose lower end is connected to the one end of the lower wiring of an adjacent coil.

3. The chip-format coil structure according to claim 1, wherein
the coil portion is made of a plated conductive metal.

4. The chip-format coil structure according to claim 1, wherein
a magnetic filler is dispersed in the resin material.

5. The chip-format coil structure according to claim 1, wherein
the substrate is made of a film of an insulating resin material.

6. The chip-format coil structure according to claim 1, wherein
the substrate is made of a film of an insulating resin material formed by electrodeposition.

7. The chip-format coil structure according to claim 1, having a thickness of 50 μm or less.

8. A method for manufacturing a chip-format coil structure including a rectangle substrate of an insulating resin material and a coil portion having a solenoid structure a part of which is embedded within the substrate and in which adjacent coils are insulated from each other by the substrate,
the method comprising the steps of:
forming successively the substrate and the coil portion on a provisional support; and
taking out the coil structure by removing the support and forming the coil portion as a coupling body including a plurality of rectangle coils, wherein
each of the rectangle coils is made by a method comprising the step of:
forming a lower wiring on the provisional support;
stacking an insulating resin material with a thickness necessary to obtain a thickness of the substrate on the provisional support;
making via holes vertically passing through a layer of the resin material;
filling the via holes with a conductive metal;
covering the surface of the layer of the resin material with a predetermined pattern; and
forming a first passing-through wiring which vertically passes through the substrate and whose lower end is connected to one end of the lower wiring, an upper wiring which is formed on the upper surface of the substrate and whose one end is connected to one upper end of the first passing-through wiring, and a second passing-through wiring which vertically passes through the substrate, whose upper end is connected to the other end of the upper wiring and whose lower end is connected to one end of the lower wiring of an adjacent coil.

9. The method for manufacturing a chip-format coil structure according to claim 8, wherein
a magnetic filler is dispersed in the resin material.

10. A semiconductor package incorporating the coil structure according to claim 1.

11. The chip-format structure according to claim 1, wherein
the fillers are employed with the grain diameter within a range of about 0.1 to 10 μm.

12. The chip-format structure according to claim 1, wherein
the dispersing degree of the fillers is within a range of 30 to 85% by weight with reference to the total weight of the resin material.
